(19) United States
(12) Patent Application Publication
(10) Pub. No.: US 2017/0363890 A1
(43) Pub. Date: Dec. 21, 2017

(54) LIQUID CRYSTAL DISPLAY DEVICE

(71) Applicant: Sharp Kabushiki Kaisha, Sakai City, Osaka (JP)

(72) Inventors: ISAMU MIYAKE, Sakai City (JP); YOHSUKE KANZAKAI, Sakai City (JP)

(21) Appl. No.: 15/533,950

(22) PCT Filed: Dec. 1, 2015
(86) PCT No.: PCT/JP2015/083675

§ 371 Date: Jun. 7, 2017

(30) Foreign Application Priority Data
Dec. 8, 2014 (JP) 2014-248054

(51) Int. Cl. G02F 1/1337; H01L 27/12; G02F 1/1368; H01L 29/786; C08F 20/10

(52) U.S. Cl. CPC G02F 1/1337; H01L 29/786; C08F 20/10; G02F 1/1368; H01L 27/1214

(57) ABSTRACT

The present invention provides a liquid crystal display device in which display unevenness is suppressed by preventing degradation of TFT characteristics due to photo-alignment treatment. The liquid crystal display device of the present invention is a liquid crystal display device including: a thin-film transistor substrate; and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the oxide semiconductor containing indium, tin, zinc, and oxygen, the alignment film having a photofunctional group.

### TECHNICAL FIELD

The present invention relates to a liquid crystal display device. More specifically, the present invention relates to a liquid crystal display device including an oxide semiconductor in a thin-film transistor substrate.

### BACKGROUND ART

Liquid crystal display devices are display devices utilizing a liquid crystal composition for display. According to a typical display mode thereof, light is incident on a liquid crystal panel including a liquid crystal composition sealed in between a pair of substrates and a voltage is applied to the liquid crystal composition to change the alignment of liquid crystal molecules, thereby controlling the amount of light passing through the liquid crystal panel. Such liquid crystal display devices have advantageous characteristics such as thin profile, light weight, and low power consumption and thus are applied in various fields.

Conventionally used materials for a channel layer included in a thin-film transistor (TFT) that is provided in each pixel of a liquid crystal display device are silicon materials such as polycrystalline silicon and amorphous silicon. Recently, oxide semiconductors have been used as materials for a channel layer with an aim of improving the performance of the TFT. A TFT including an oxide semiconductor (In—Ga—Zn—O oxide semiconductor) containing indium, gallium, zinc, and oxygen has been mass-produced.

Along with the recent development of higher definition liquid crystal display devices, the area of a pixel has been reduced. A pixel-driving TFT is therefore desired to be smaller to increase the aperture ratio of the pixel. A known structure advantageous for downsizing of the TFT is channel-etch (CE) structure.

The alignment of liquid crystal molecules in a state where no voltage is applied is normally controlled by an alignment film subjected to alignment treatment. Conventionally, rubbing is widely employed as an alignment treatment technique. Recently, research and development have been made on a photo-alignment method that enables contactless alignment treatment (for example, see Patent Literature 1).

### CITATION LIST

### Patent Literature

Patent Literature 1: WO 2012/050177

### SUMMARY OF INVENTION

### Technical Problem

In the case where a photolysis alignment film including a cyclobutane structure is used for the photo-alignment treatment, the threshold voltage (Vth) of the TFT may be lowered (negative shift). The use of an electrostatic chuck or a transfer step in production of liquid crystal display devices may cause static generation, and through a pixel transistor subjected to the negative shift, information of the static is unintendedly written into the corresponding pixel. As a result, a direct current (DC) potential applied to the liquid crystal causes a residual DC voltage in the liquid crystal, leading to display unevenness (nonuniform DC charging).

The present invention has been devised under the current situation in the art, and aims to provide a liquid crystal display device in which display unevenness is suppressed by preventing degradation of TFT characteristics due to photo-alignment treatment.

### Solution to Problem

In the research on the degradation of TFT characteristics due to photo-alignment treatment, the inventors of the present invention noted that TFT characteristics are degraded when the TFT has a channel etch (CE) structure and an In—Ga—Zn—O oxide semiconductor is used in a channel layer. As a result of study on the cause of the degradation of TFT characteristics, they found the followings. When the channel layer includes an In—Ga—Zn—O oxide semiconductor, the In—Ga—Zn—O oxide semiconductor is damaged during a process of forming the CE structure. The damaged In—Ga—Zn—O oxide semiconductor generates electron-hole pairs upon irradiation with light. Due to the generation of electron-hole pairs, current-voltage characteristics (I-V characteristics) of the TFT are shifted to the negative side, leading to display unevenness.

As a result of further intensive study, the present inventors found an oxide semiconductor that is less damaged during a process of forming a CE structure and is less likely to generate electron-hole pairs when irradiated with light, compared to an In—Ga—Zn—O oxide semiconductor. Specifically, they found out that the use of an oxide semiconductor (In—Sn—Zn—O oxide semiconductor) containing indium, tin, zinc, and oxygen in a channel layer can provide TFT characteristics that are at least comparable to those provided by the use of an In—Ga—Zn—O oxide semiconductor in a channel layer, as well as preventing degradation of the TFT characteristics due to photo-alignment treatment. The inventors of the present invention have thus solved the above problems to complete the present invention.

Specifically, an aspect of the present invention may be a liquid crystal display device including: a thin-film transistor substrate; and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the oxide semiconductor containing indium, tin, zinc, and oxygen, the alignment film having a photofunctional group.

### Advantageous Effects of Invention

Since the liquid crystal display device of the present invention includes a channel layer including an oxide semiconductor (In—Sn—Zn—O oxide semiconductor) that contains indium, tin, zinc, and oxygen, damage of the channel layer during channel etching can be prevented. Degradation of the current-voltage (I-V) characteristics of the TFT due to the photo-alignment treatment can be thus prevented. This can prevent nonuniform DC charging due to TFT characteristics, leading to a liquid crystal display device excellent in display quality.

### BRIEF DESCRIPTION OF DRAWINGS

FIG. 1 is a cross-sectional view schematically illustrating a structure of a liquid crystal display device of Example 1.

FIG. 2 is a cross-sectional view schematically illustrating a thin-film transistor substrate of Example 1.

FIG. 3 is a plan view schematically illustrating a pixel of the thin-film transistor substrate of Example 1.

FIG. 4 is a view showing an irradiation spectrum of an alignment treatment in Example 1.

FIG. 5 is a graph showing current-voltage characteristics of a TFT of Example 1 analyzed before and after exposure for the alignment treatment.

FIG. 6 is a view showing an irradiation spectrum of an alignment treatment in Comparative Example 1.

FIG. 7 is a graph showing current-voltage characteristics of a TFT of Comparative Example 1 analyzed before and after exposure for the alignment treatment.

FIG. 8 is a view showing an irradiation spectrum of an alignment treatment in Example 2.

FIG. 9 is a view showing an irradiation spectrum of an alignment treatment in Example 3.

FIG. 10 is a cross-sectional view schematically illustrating a thin-film transistor substrate of Example 4.

FIG. 11 is a plan view schematically illustrating a pixel of the thin-film transistor substrate of Example 4.

FIG. 12 is a view showing an irradiation spectrum of an alignment treatment in Example 4.

FIG. 13 is a view showing an irradiation spectrum of an alignment treatment in Example 5.

### DESCRIPTION OF EMBODIMENTS

Embodiments of the present invention are described in the following. The present invention is not limited to the contents described in the following embodiments, and may be appropriately modified within a range where the configuration of the present invention is satisfied.

The liquid crystal display device of the present embodiment is a liquid crystal display device including: a thin-film transistor substrate; and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the oxide semiconductor containing indium, tin, zinc, and oxygen, the alignment film having a photofunctional group.

The thin-film transistor substrate includes a thin-film transistor (TFT) having a channel etch structure. The channel etch structure is provided to a TFT when a conductive film is directly stacked on a channel layer, without providing a layer protecting the channel layer (etching stopper), and a source electrode and a drain electrode are formed by dividing the conductive film by channel etching. In other words, in the channel etch structure, no etching stopper is present on the channel layer, and the source electrode and the drain electrode are present closer to the alignment film than the channel layer. In a TFT having such a channel etch structure, when the channel layer includes an In—Ga—Zn—O oxide semiconductor, the channel layer is damaged by channel etching and therefore likely to generate a photo-leakage current in the channel layer.

The channel etch structure is advantageous to shorten the channel length. Specifically, in the channel etch structure, the distance between the source electrode and the drain electrode directly corresponds to the channel length, while in the etching stopper (ES) structure, the distance between a portion where the source electrode contacts the channel layer and a portion where the drain electrode contacts the channel layer corresponds to the channel length. Accordingly, in the case where the photolithography devices of the same resolution limit are used, the channel length is inevitably shorter in the channel etch structure. With the shorter channel length, the TFT has better drive power, so that the channel, width can be also reduced.

The TFT includes a gate electrode, a gate insulating film, a channel layer containing an oxide semiconductor, and a pair of a source electrode and a drain electrode in the stated order. Namely, the TFT has a bottom gate structure. In the bottom gate structure, the gate electrode is formed prior to the channel layer, and therefore, the surface of the channel layer is not covered with the gate electrode. Accordingly, light of the photo-alignment treatment is incident on the surface of the channel layer without being shielded by the gate electrode.

As above, the respective members included in the TFT substrate are stacked in the order of (1) the gate electrode, (2) the gate insulating film, (3) the channel layer, and (4) the source electrode and the drain electrode based on their formation order. The side of (4) the source electrode and the drain electrode is closer to the alignment film.

Examples of the material of the gate electrode include high-melting-point metals such as tungsten, molybdenum, tantalum, and titanium, and nitrides of high-melting-point metals. The gate electrode may be either a single-layer electrode or an electrode including two or more layers laminated to each other.

Examples of the material of the gate insulating film include insulating materials such as silicon dioxide (SiO₂), silicon nitride (SiNx), tantalum oxide, and aluminum oxide.

The oxide semiconductor used in the channel layer contains indium, tin, zinc, and oxygen, and is herein also referred to as an “In—Sn—Zn—O oxide semiconductor”. The In—Sn—Zn—O oxide semiconductor has higher resistance against an etchant or etching gas used for removal of a conductive film in a channel etching step, compared to an In—Ga—Zn—O oxide semiconductor, and therefore is less damaged in the process of forming a CE structure and is presumably less likely to generate electron-hole pairs when irradiated with light. The etchant is, for example, a PAN (phosphoric, acetic, and nitric acids) etchant.

While the In—Ga—Zn—O oxide semiconductor is soluble in a PAN etchant, the In—Sn—Zn—O oxide semiconductor is insoluble in a PAN etchant. Therefore, in the case where the source electrode and the drain electrode each include a laminate (Al/Mo) of an Al film with a thickness of 300 nm and a Mo film with a thickness of 50 nm, channel etching can be performed by wet etching using a PAN etchant.

In the case where the source electrode and the drain electrode each include a laminate (Ti/Al/Ti) of a Ti film, an Al film, and a Ti film, dry etching is performed. The etching gas used is, for example, a chlorine gas such as Cl₂ or BCl₃.

The wet etching is more preferred because the channel layer is not damaged in a process of channel etching, while the channel layer is damaged by plasma in the dry etching.

The In—Sn—Zn—O oxide semiconductor exhibits excellent electron mobility and can realize a thin film transistor that is less likely to suffer a leakage current.

The In—Sn—Zn—O oxide semiconductor preferably has a composition satisfying the following ratios where the number of indium atoms is represented by [In], the number of tin atoms is represented by [Sn], and the number of zinc atoms is represented by [Zn]:

0.2<[In]/([In]+[Sn]+[Zn])<0.4,

0.1<[Sn]/([In]+[Sn]+[Zn])<0.4,

0.2<[Zn]/([In]+[Sn]+[Zn])<0.7.

Examples of the material of the source electrode and drain electrode include metals such as titanium, chromium, aluminum, and molybdenum, and alloys of these. The source electrode and drain electrode each may be either a single-layer electrode or an electrode including two or more layers laminated to each other. The source electrode and drain electrode can be formed, for example, by etching ( channel etching) a conductive film by photolithography. Specifically, treatment is performed in the order of application of a resist, pre-baking, exposure, development, post-baking, dry etching, and resist stripping, thereby patterning the conductive film.

The TFT is preferably a pixel TFT present in a display region. In the case of a drive TFT present in a region other than the display region such as a frame region, generation of a photo-leakage current may be suppressed by shielding light of the photo-alignment treatment. By contrast, since light of the photo-alignment treatment cannot be shielded in the display region, generation of a photo-leakage current is desired to be prevented by using an In—Sn—Zn—O oxide semiconductor to reduce the damage of the channel layer.

The alignment film is arranged on the liquid crystal layer side surface of the TFT substrate and controls the alignment of liquid crystal molecules in the liquid crystal layer. When the voltage applied to the liquid crystal layer is smaller than the threshold voltage (including a case of applying no voltage), the alignment of liquid crystal molecules in the liquid crystal layer is mainly controlled by the alignment film.

The alignment film has a photofunctional group. The photofunctional group refers to a functional group that is structurally changed by irradiation with light (electromagnetic wave) such as ultraviolet light or visible light. The alignment film is a so-called photo-alignment film, having a photofunctional group to show photo-alignment properties. Materials that show photo-alignment properties refer to overall materials which, when irradiated with light, exhibit properties (alignment regulating force) of regulating the alignment of liquid crystal molecules present therearound or change the level of the alignment regulating force and/or the direction of the alignment.

The alignment film may include any photofunctional group, and preferably includes at least one selected from the group consisting of a cinnamate structure, a chalcone structure, a cyclobutane structure, an azobenzene structure, a stilbene structure, a coumarin structure, and a phenyl ester structure. These structures enable the alignment treatment with light. In polymers included in the alignment film, the cinnamate structure, chalcone structure, cyclobutane structure, azobenzene structure, stilbene structure, coumarin structure, and phenyl ester structure may be included in either the main chain or a side chain.

The cinnamate structure, chalcone structure, coumarin structure, and stilbene structure each are a photofunctional group which develops dimerization (dimer formation) and isomerization by irradiation with light or a group resulting from dimerization or isomerization of the photofunctional group. The cyclobutane structure is a photofunctional group that undergoes ring-opening decomposition by irradiation with light. The azobenzene structure is a photofunctional group which develops isomerization by irradiation with light or a group resulting from isomerization of the photofunctional group. The phenyl ester structure is a photofunctional group which develops photo-fries rearrangement by irradiation with light or a group resulting from photo-fries rearrangement of the photofunctional group.

The alignment film may be either a single-layer film or a film including two or more layers laminated to each other.

The alignment film can be formed by treatment performed in the order of application of an alignment agent containing a material that shows photo-alignment properties, pre-baking, exposure for alignment treatment, and post-baking, or in the order of application of an alignment agent containing a material that shows photo-alignment properties, pre-baking, post-baking, and exposure for alignment treatment.

On the liquid crystal layer side surface of the alignment film, a polymer layer may be formed by polymer sustained alignment (PSA). In the PSA, a liquid crystal material that contains a photopolymerizable monomer (precursor) and liquid crystal molecules is sealed in a liquid crystal panel, and irradiated with light so that the photopolymerizable monomer is photopolymerized. The polymer resulting from the photopolymerization has lower solubility into a liquid crystal material than the photofunctional monomer, so that a polymer layer can be formed on the alignment film. The photopolymerizable monomer used is preferably, for example, an acrylate monomer or a methacrylate monomer as it can be efficiently radically polymerized with light. A polymer layer to be formed by polymerization of the acrylate monomer and/or methacrylate monomer includes an acrylate structure and/or a methacrylate structure.

Examples of the acrylate monomer and methacrylate monomer include monomers represented by the formula (C):

A1(R1)ₙ-Y-(R2)ₘ-A2 (C),

wherein Y represents a structure including at least one (condensed) benzene ring in which a hydrogen atom may be substituted with a halogen atom; at least one of A1 and A2 represents acrylate or methacrylate, A1 and A2 are bonded to the (condensed) benzene ring via R1 and R2; R1 and R2 each represent a spacer, specifically, an alkyl chain having a carbon number of 10 or smaller in which a methylene group may be substituted with a functional group selected from ester, ether, amide, and ketone groups, and a hydrogen atom may be substituted with a halogen atom; n and m are each 0 or 1, and no spacer is provided when n and m both represent 0.

The skeleton Y in the formula (C) is preferably a structure represented by the formula (C-1), (C-2), or (C-3). Hydrogen atoms in the formulae (C-1), (C-2), and (C-3) may be each independently substituted with a halogen atom, a methyl group, or an ethyl group.

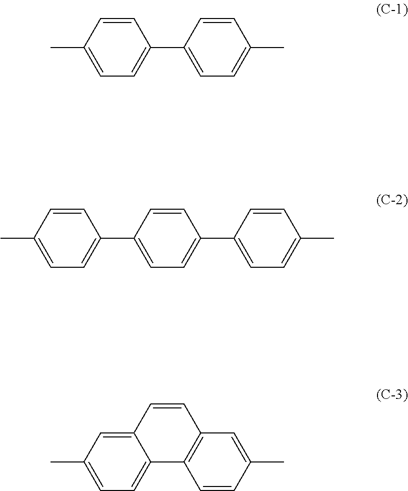

Specific examples of the monomer represented by the formula (C) include those represented by the formulae (C-1-1), (C-1-2), and (C-3-1).

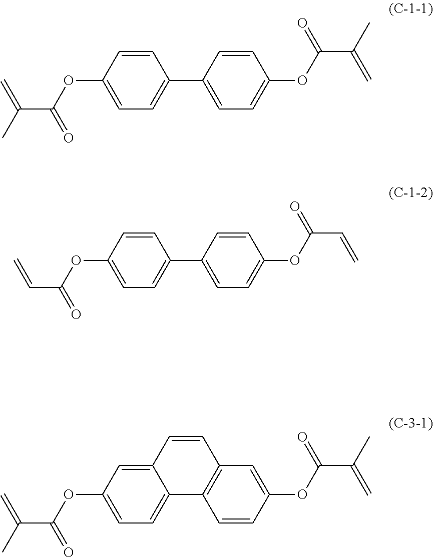

The polymer layer formed by PSA may be either a film covering the entire surface of the alignment film or a film dispersively formed on the alignment film.

The pretilt angle (angle formed between the surface of the alignment film and the major axis of the liquid crystal molecules) of the liquid crystal molecules provided by the alignment film (or the alignment film and the polymer layer) is not particularly limited. The alignment film may be either a horizontal alignment film or a vertical alignment film. In the case of the horizontal alignment film, used for a transverse electric field mode such as an IPS mode and an FFS mode, the pre-tilt angle is preferably substantially 0° (for example, smaller than 10°), more preferably 0°. In the case of the horizontal alignment film used for a vertical electric field mode such as a TN mode and an STN mode, the pre-tilt angle is preferably 0.5° or larger and smaller than 25°, more preferably 1° or larger and smaller than 10°.

The liquid crystal layer may be one commonly used in a liquid crystal display device in which the initial alignment of the liquid crystal is controlled by an alignment film. The anisotropy of dielectric constant (Δε) defined by the formula (P) of the liquid crystal molecules contained in the liquid crystal layer may be either negative or positive. In other words, the liquid crystal molecules may have either negative anisotropy of dielectric constant or positive anisotropy of dielectric constant. The liquid crystal molecules having negative anisotropy of dielectric constant used may have Δε of, for example, −1 to −20. The liquid crystal molecules having positive anisotropy of dielectric constant used may have Δεof, for example, 1 to 20.

Δε=(Dielectric constant in the major axis direction)−(Dielectric constant in the minor axis direction) (P)

The display mode of the liquid crystal display device of the present embodiment is not particularly limited, and may be, for example, a horizontal alignment mode such as a fringe field switching (FFS) mode or an in-plane switching (IPS) mode; a vertical alignment mode such as a vertical alignment twisted nematic (VATN) mode, a multi-domain vertical alignment (MVA) mode, or a patterned vertical alignment (PVA) mode; or a twisted nematic (TN) mode.

In the horizontal alignment mode, the thin-film transistor substrate is provided with a pair of electrodes configured to apply an electric field to the liquid crystal layer. In the FFS mode, the thin-film transistor substrate is provided with a structure (FFS electrode structure) including a planar electrode, a slit electrode, and an insulating film placed between the planar electrode and the slit electrode, and an oblique electric field (fringe electric field) is created in the liquid crystal layer adjacent to the thin-film transistor substrate. Normally, the slit electrode, the insulating film, and the planar electrode are arranged in the stated order from the liquid crystal layer side. The slit electrode may be, for example, an electrode provided with, as a slit, a linear aperture with its whole circumference surrounded by the electrode or a comb-shaped electrode in which multiple teeth portions are provided and linear cut portions between the teeth portions form slits.

In the IPS mode, the thin-film transistor substrate is provided with a pair of comb-shaped electrodes and a transverse electric field is created in the liquid crystal layer adjacent to the thin-film transistor substrate. The pair of comb-shaped electrodes may be, for example, a pair of electrodes each provided with multiple teeth portions, arranged in such a manner that the teeth portions mesh with each other.

In a VATN-mode liquid crystal display device, alignment treatment is performed in multiple directions to each pixel, and therefore, the alignment treatment with light is suitably employed. In such a VATN-mode liquid crystal display device too, the effect of preventing degradation of TFT characteristics can be achieved according to the present invention.

The liquid crystal display device of the present embodiment may include, in addition to the thin-film transistor substrate and the liquid crystal layer, members such as a color filter substrate; a polarizing plate; a backlight; an optical film such as a phase difference film, a viewing angle expansion film, or a brightness enhancement film; an external circuit such as a tape carrier package (TCP) or a printed circuit board (PCB); and a bezel (frame). These members are not particularly limited, and those commonly used in the field of liquid crystal display devices may be used. Therefore, descriptions thereof are omitted.

Here, each and every detail described for the above embodiment of the present invention shall be applied to all the aspects of the present invention.

The present invention is more specifically described in the following based on examples and comparative examples with reference to drawings. The examples, however, are not intended to limit the present invention.

### EXAMPLE 1

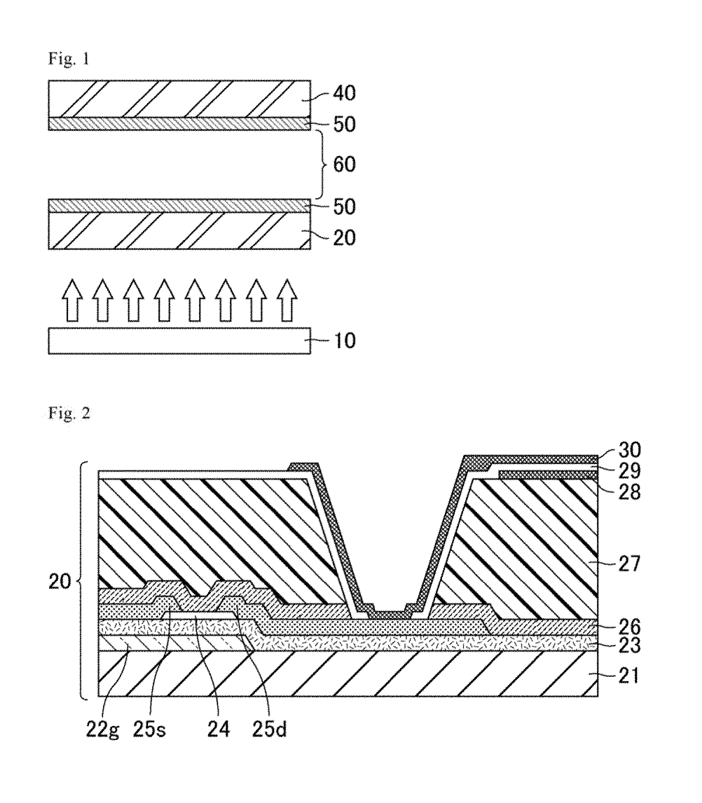

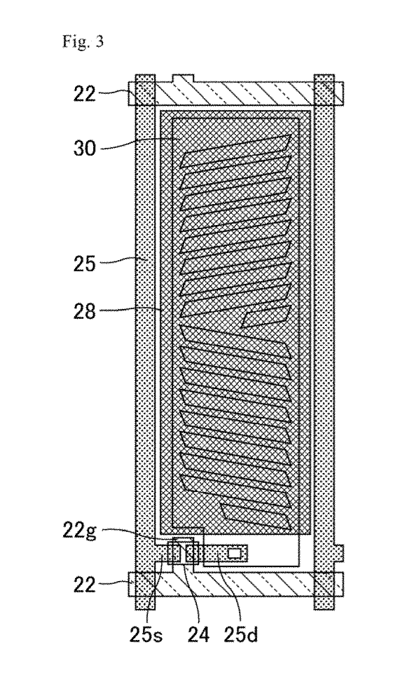

Example 1 relates to a liquid crystal display device of the fringe field switching (FFS) mode that is a horizontal alignment mode. FIG. 1 is a cross-sectional view schematically illustrating a structure of a liquid crystal display device of Example 1. FIG. 2 is a cross-sectional view schematically illustrating a thin-film transistor substrate of Example 1. FIG. 3 is a plan view schematically illustrating a pixel of the thin-film transistor substrate of Example 1.

As illustrated in FIG. 1, the liquid crystal display device of Example 1 included, from the back side toward the viewer side, a backlight 10, a thin-film transistor (TFT) substrate 20, an alignment film 50, a liquid crystal layer 60, an alignment film 50, and a color filter (CF) substrate 40 in the stated order. Void arrows in FIG. 1 schematically indicate the travel direction of light emitted from the backlight 10.

As illustrated in FIG. 2, the TFT substrate 20 had a bottom gate-type channel etch (CE) structure. Specifically, on the substrate 21, a gate electrode 22g that was a laminate (W/TaN) of a tungsten film with a thickness of 300 nm and a tantalum nitride film with a thickness of 20 nm was provided in a predetermined pattern. As illustrated in FIG. 3, the gate electrode 22g was branched from the gate line 22.

On the gate electrode 22g was provided a gate insulating film 23 that was a laminate (SiO₂/SiNₓ) of a silicon oxide film with a thickness of 50 nm and a silicon nitride film with a thickness of 300 nm to cover the entire surface of the substrate.

On the gate insulating film 23 was provided a channel layer 24 including an oxide semiconductor with a thickness of 50 nm. The oxide semiconductor used contained indium, tin, zinc, and oxygen (In—Sn—Zn—O oxide semiconductor). The channel layer 24 was formed by forming the oxide semiconductor into a film by sputtering and patterning the formed film as desired by photolithography including a wet etching step and a resist stripping step.

On the channel layer 24 were provided a source electrode 25s and a drain electrode 25d each of which was a laminate (Ti/Al/Ti) including a titanium film with a thickness of 100 nm, an aluminum film with a thickness of 300 nm, and a titanium film with a thickness of 30 nm, in a predetermined pattern. As illustrated in FIG. 3, the source electrode 25s was branched from the source line 25, and the drain electrode 25d was placed to oppose the source electrode 25s across the channel layer 24. The source electrode 25s and the drain electrode 25d were formed by forming the laminate on the entire surface of the substrate 21 by sputtering and then patterning the laminated film by photolithography including a dry etching step (channel etching) and a resist stripping step. In the dry etching step, the laminate formed on the channel layer 24 was partly removed to have a predetermined channel length (L=4 μm) and channel width (W=4 μm).

On the source electrode 25s and the drain electrode 25d was provided an inorganic insulating film 26 that was a silicon oxide film (SiO₂) with a thickness of 300 nm to cover the entire surfaces of the substrates. An acrylic resin film 27 with a thickness of 2.0 μm was further provided to cover the entire surfaces of the substrates.

Since the liquid crystal display device of the present example is of the FFS mode, an auxiliary capacitance electrode 28 that was an indium-zinc-oxygen film (IZO) with a thickness of 100 nm was provided in a predetermined pattern on the acrylic resin film 27. An aperture penetrating the inorganic insulating film 26 and the acrylic resin film 21 was further formed to partly expose the drain electrode 25d.

Subsequently, an auxiliary capacitance insulating film 29 that was a silicon nitride (SiNₓ) film with a thickness of 100 nm was provided except for the region where the drain electrode 25d was partly exposed. Further, a pixel electrode 30 that was an indium-zinc-oxygen (IZO) film with a thickness of 100 nm was provided in a predetermined pattern. As described above, a TFT substrate having the structure as illustrated in FIG. 2 and FIG. 3 was produced.

Though not illustrated in FIG. 2, an alignment film 50 was provided on the pixel electrode 30. The alignment film 50 was also formed on the surface of the CF substrate 40 on the side adjacent to the liquid crystal layer 60.

The alignment films 50 were formed by the following procedure. First, an alignment agent containing, as a solid content, a polyimide polymer that included a cyclobutane structure in the main chain was applied to the TFT substrate 20. The alignment agent had a composition of N-methyl-2-pyrrolidone (NMP):butyl cellosolve (BC):solid content=66:30:4 (weight ratio). The same alignment agent was also applied to the CF substrate 40.

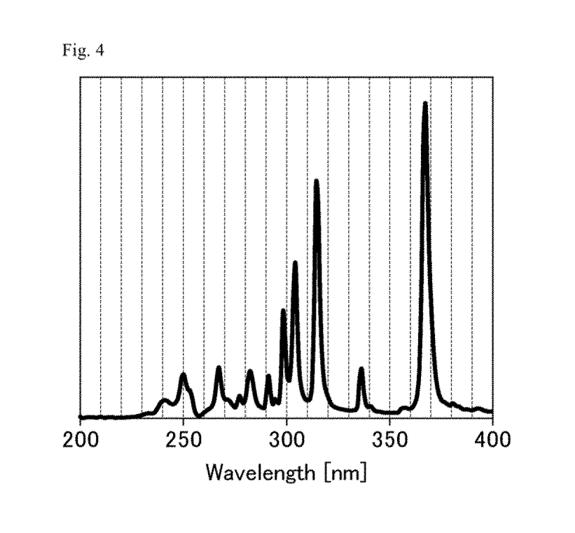

The TFT substrate 20 and the CF substrate 40 each with the alignment agent applied thereto were pre-baked at 70° C. for two minutes. The alignment films formed by the pre-baking each had a thickness of 100 nm. After the pre-baking, the alignment films were post-baked at 230° C. for 30 minutes. After the post-baking, irradiation with polarized ultraviolet rays in the normal direction of the substrate was performed as exposure for alignment treatment. FIG. 4 is a view showing an irradiation spectrum of the alignment treatment in Example 1. The light source of the polarized ultraviolet rays used was a high-intensity point light source (produced by Ushio Inc., trade name: Deep UV lamp). No bandpass filter was used. The polarized ultraviolet rays with which the alignment films 50 were irradiated had an intensity measured with an accumulated UV meter (produced by Ushio Inc., trade name: UIT-250, photodetector type: UVD-S365) of 0.6 J/cm². After the exposure for alignment treatment, the alignment films 50 were additionally baked at 230° C. for 30 minutes.

Next, a predetermined pattern was drawn with a sealing agent (produced by Kyoritsu Chemical & Co., Ltd., trade name: WORLD ROCK) on the CF substrate 40. Then, a liquid crystal was dropped to the TFT substrate 20 by one drop filling (ODF). The liquid crystal used was MLC6610 (Δε=−3.1) produced by Merck KGaA. The CF substrate 40 and the TFT substrate 20 were attached to each other in such a manner that the polarization axes of the polarized ultraviolet rays in the alignment treatment coincided with each other, and the liquid crystal was sealed in between the TFT substrate 20 and the CF substrate 40. The heat treatment was then carried out at 130° C. for 40 minutes. The formed liquid crystal layer 60 had a d·Δn (product of the thickness d and the refractive index anisotropy Δn) of 330 nm. A pair of polarizing plates was attached to the back side of the TFT substrate 20 and the viewing surface side of the CF substrate 40 in such a manner that the polarization axes were in a relation of crossed Nicols. Further, the backlight 10 equipped with a light emitting diode (LED) was mounted on the back side of the TFT substrate 20, thereby completing the FFS-mode liquid crystal display device of Example 1.

### <Characteristics Evaluation of Example 1>

### 1) Current-Voltage (I-V) Characteristics of TFT

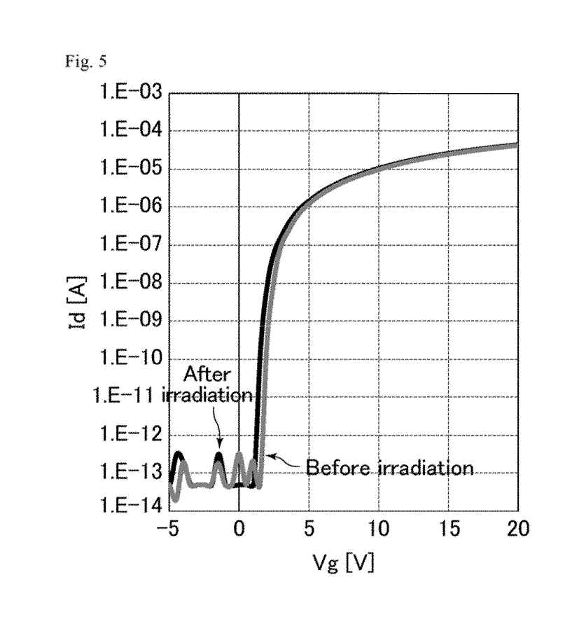

The I-V characteristics of the TFT of Example 1 were analyzed before and after the exposure for alignment treatment using a semiconductor parameter analyzer 4156C produced by Agilent Technologies. In the analysis, the voltage between the source electrode 25s and the drain electrode 25d was set to 10 V (Vds=10 V), and the amount of the current (Id) flowing in the channel layer 24 upon change of the voltage (Vg) of the gate electrode 22g was measured. FIG. 5 is a graph showing the current-voltage characteristics of the TFT of Example 1 analyzed before and after the exposure for alignment treatment. As shown in FIG. 5, the I-V characteristics were hardly changed before and after the exposure for alignment treatment. Specifically, the threshold voltage of the TFT was lowered by 0.43 V (ΔVth=−0.43 V) after the exposure.

### 2) Display Unevenness at a Gray Scale Value of 31

The screen lit at the gray scale value of 31 was visually observed to evaluate the display unevenness. The gray scale value of 31 corresponds to the rising portion of the voltage-transmittance curve (V-T line) and shows a steep change of the transmittance against the voltage change, so that the display unevenness tends to be significant. As a result of the observation, the liquid crystal display device of Example 1 had favorable display quality without display unevenness through a neutral density filter (ND20 filter) that passes 20% of light. When the screen is directly observed not through the ND20 filter, slight display unevenness was observed. However, since the display unevenness was only slight one that could not be observed through the ND20 filter, the display unevenness was not recognizable under an actual use condition where the gray scale values other than the gray scale value of 31 are used and considered to be practically acceptable.

### COMPARATIVE EXAMPLE 1

An FFS-mode liquid crystal display device was produced in the same manner as in Example 1, except that the channel layer 24 was formed using an In—Ga—Zn—O oxide semiconductor.

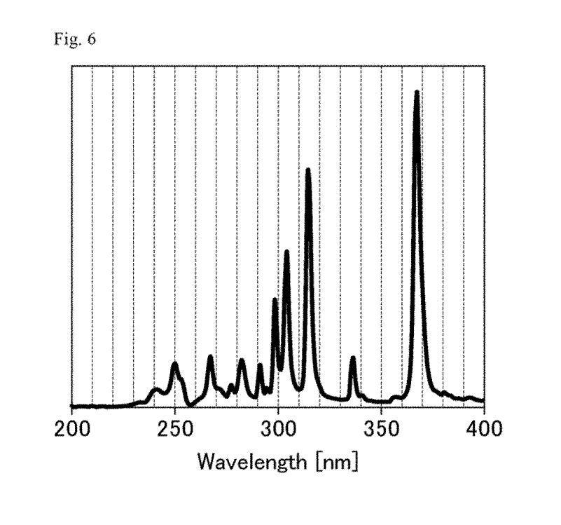

FIG. 6 is a view showing the irradiation spectrum of the alignment treatment in Comparative Example 1. The light source of the polarized ultraviolet rays used was a high-intensity point light source (produced by Ushio Inc., trade name: Deep UV lamp). No bandpass filter was used. The polarized ultraviolet rays with which the alignment films were irradiated had an intensity measured with an accumulated UV meter (produced by Ushio Inc., trade name: UIT-250, photodetector type: UVD-S254) of 0.6 J/cm²,

### <Characteristics Evaluation of Comparative Example 1>

### 1) Current-Voltage (I-V) Characteristics of TFT

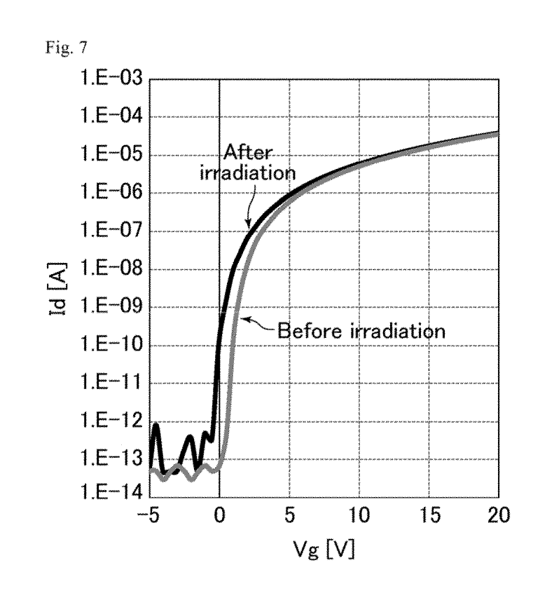

The I-V characteristics of the TFT of Comparative Example 1 were analyzed before and after the exposure for alignment treatment in the same manner as in Example 1. FIG. 7 is a graph showing the current-voltage characteristics of the TFT of Comparative Example 1 analyzed before and after the exposure for alignment treatment. As shown in FIG. 7, the I-V characteristics were obviously changed before and after the exposure for alignment treatment. Specifically, the threshold voltage of the TFT was lowered by 0.89 V (ΔVth=−0.89 V) after the exposure.

### 2) Display Unevenness at a Gray Scale Value of 31

The screen lit at the gray scale value of 31 was visually observed to evaluate the display unevenness. As a result of the observation, the liquid crystal display device of Comparative Example 1 had display unevenness even through a neutral density filter (ND10 filter) that passes 10% of the light. Namely, the liquid crystal display device of Comparative Example 1 did not have enough display quality. The display unevenness is presumably caused by nonuniform DC charging due to the TFT characteristics.

### [Consideration About the Evaluation Results of Example 1 and Comparative Example 1]

The threshold voltage of the TFT of Comparative Example 1 was significantly lowered by the exposure for alignment treatment, leading to display unevenness. In the TFT having a channel etch (CE) structure, the surface of the channel layer (back channel) is exposed in the dry etching process for separating a source electrode and a drain electrode, to be exposed to plasma discharge. In the case where the channel layer includes an In—Ga—Zn—O oxide semiconductor as in Comparative Example 1, plasma discharge creates a defect level in the channel layer which mainly generates electron-hole pairs when irradiated with light for the alignment treatment. As a result, the I-V characteristics of the TFT are presumably negatively shifted. The spectrum of the light used in the alignment treatment included ultraviolet rays having a short wavelength of 350 nm or shorter which may give a significant influence on the characteristics of the oxide semiconductor (In—Ga—Zn—O included in the channel layer of Comparative Example 1.

By contrast, in Example 1, since the channel layer included an In—Sn—Zn—O oxide semiconductor, the surface of the channel layer was not damaged by plasma discharge, presumably resulting in significant reduction in creation of a defect level.

### EXAMPLE 2

An FFS-mode liquid crystal display device was produced in the same manner, except for the formation of the alignment film, as in Example 1.

The alignment film was formed by the following procedure. First, an alignment agent containing, as a solid content, a polyimide polymer that included an azobenzene structure in the main chain was applied to the TFT substrate. The alignment agent had a composition of NMP:BC:solid content=66:30:4 (weight ratio). The same alignment agent was also applied to the CF substrate.

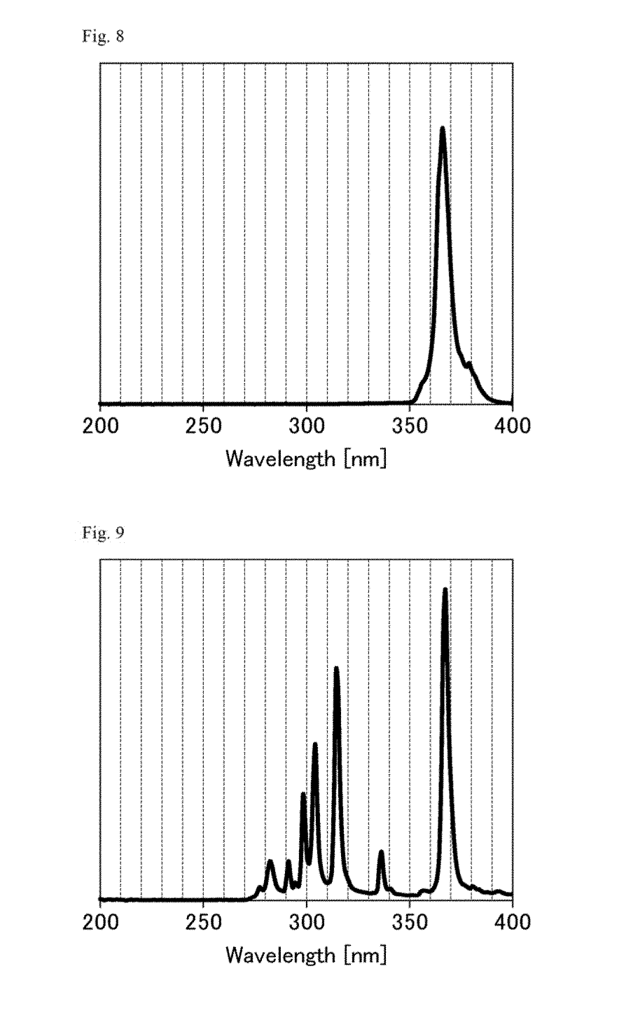

The TFT substrate and the CF substrate each with the alignment agent applied thereto were pre-baked at 70° C. for two minutes. The alignment films formed by the pre-baking each had a thickness of 100 nm. After the pre-baking, irradiation with polarized ultraviolet rays in the normal direction of the substrate was performed as exposure for alignment treatment. FIG. 8 is a view showing an irradiation spectrum of the alignment treatment in Example 2. The light source of the polarized ultraviolet rays used was a high-intensity point light source (produced by Ushio Inc., trade name: Deep UV lamp). Further, a band pass filter that passes light having a wavelength of 365 nm was used. The polarized ultraviolet rays with which the alignment films were irradiated had an intensity measured with an accumulated UV meter (produced by Ushio Inc., trade name: UIT-250, photodetector type: UVD-S365) of 1 J/cm². After the exposure for alignment treatment, the alignment films were post-baked at 110° C. for 30 minutes and then at 230° C. for 30 minutes.

### <Characteristics Evaluation of Example 2>

### 1) Current-Voltage (I-V) Characteristics of TFT

The I-V characteristics of the TFT of Example 2 were analyzed before and after the exposure for alignment treatment in the same manner as in Example 1. As a result, the I-V characteristics were hardly changed before and after the exposure for alignment treatment. Specifically, the threshold voltage of the TFT was lowered by 0.02 V (ΔVth=−0.02 V) after the exposure.

### 2) Display Unevenness at a Gray Scale Value of 31

The screen lit at the gray scale value of 31 was visually observed to evaluate the display unevenness. As a result of the observation, the liquid crystal display device of Example 2 had favorable display quality without display unevenness. Accordingly, it was confirmed that nonuniform DC charging due to the TFT characteristics did not occur.

### 3) Consideration About Evaluation Results

The TFT characteristics were better than those of Example 1 because, in addition to the use of the In—Sn—Zn—O oxide semiconductor in the channel layer similarly to Example 1, the band pass filter that passes a wavelength of 365 nm was used in the exposure for alignment treatment.

### Example 3

An FFS-mode liquid crystal display device was produced in the same manner, except for the formation of the alignment film, as in Example 1.

The alignment films were formed by the following procedure. First, an alignment agent containing, as a solid content, a polyimide polymer that included a cinnamate structure in the main chain was applied to the TFT substrate. The alignment agent had a composition of NMP:BC:solid content=66:30:4 (weight ratio). The same alignment agent was also applied to the CF substrate.

The TFT substrate and the CF substrate each with the alignment agent applied thereto were pre-baked at 70° C. for two minutes. The alignment films formed by the pre-baking each had a thickness of 100 nm. After the pre-baking, irradiation with polarized ultraviolet rays in the normal direction of the substrate was performed as the exposure for alignment treatment. FIG. 9 is a view showing an irradiation spectrum of an alignment treatment in Example 3. The light source of the polarized ultraviolet rays used was a high-intensity point light source (produced by Ushio Inc., trade name: Deep UV lamp). Further, a shortcut filter that blocks light having a wavelength of 270 nm or shorter was used. The polarized ultraviolet rays with which the alignment films were irradiated had an intensity measured with an accumulated UV meter (produced by Ushio Inc., trace name: UIT-250, photodetector type: UVD-S313) of 1 J/cm². After the exposure for alignment treatment, the alignment film was post-baked at 230° C. for 30 minutes.

### <Characteristics Evaluation of Example 3>

### 1) Current-Voltage (I-V) Characteristics of TFT

The I-V characteristics of the TFT of Example 3 were analyzed before and after the exposure for alignment treatment in the same manner as in Example 1. As a result, the I-V characteristics were slightly changed before and after the exposure for alignment treatment. Specifically, the threshold voltage of the TFT was lowered by 0.18 V (ΔVth=−0.18 V) after the exposure.

### 2) Display Unevenness at a Gray Scale Value of 31

The screen lit at the gray scale value of 31 was visually observed to evaluate the display unevenness. As a result of the observation, the liquid crystal display device of Example 3 had favorable display quality without display unevenness (nonuniform DC charging due to TFT characteristics) through a neutral density filter (ND2 filter) that passes 50% of light.

### 3) Consideration About Evaluation Results

The TFT characteristics were better than those of Example 1 because, in addition to the use of the In—Sn—Zn—O oxide semiconductor in the channel layer similarly to Example 1, the shortcut filter that blocks light with a wavelength of 270 nm or shorter was used in the exposure for alignment treatment. This indicates that the defect level of the oxide semiconductor (In—Sn—Zn—O) that shifts the I-V characteristics is excited with light having a wavelength of 270 nm or shorter.

### EXAMPLE 4

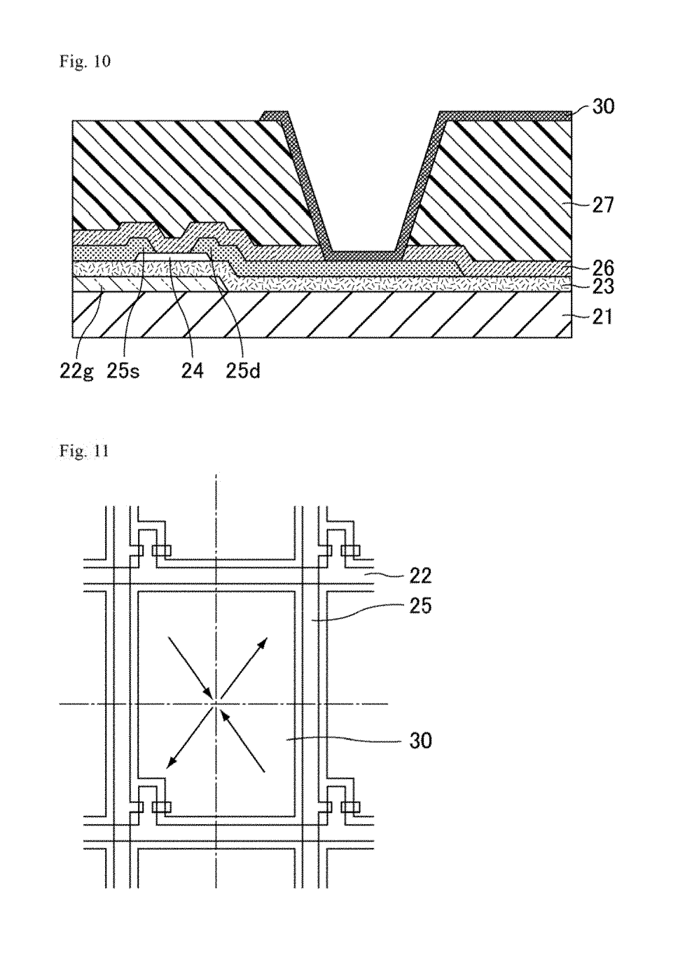

Example 4 relates to a liquid crystal display device of the vertical alignment twisted nematic (VATN) mode that is a vertical alignment mode. FIG. 10 is a cross-sectional view schematically illustrating a thin-film transistor substrate of Example 4. FIG. 11 is a plan view schematically illustrating a pixel of the thin-film transistor substrate of Example 4. The liquid crystal display device of Example 4 also had a structure illustrated in FIG. 1.

The thin-film transistor substrate (TFT substrate) 20 of Example 4 had a cross-sectional structure different from that of the TFT substrate 20 of Example 1 in that it had a channel etch (CE) structure as illustrated in FIG. 10 and included no auxiliary capacitance electrode 28 or auxiliary capacitance insulating film 29.

Though not illustrated in FIG. 10, the alignment film 50 was provided on the pixel electrode 30. The alignment film 50 was also formed on the surface of the color filter substrate (CF substrate) 40 on the side adjacent to the liquid crystal layer 60.

The alignment films 50 were formed by the following procedure. First, an alignment agent containing, as a solid content, a polyimide polymer that included a cinnamate structure and an alkyl fluoride chain in a side chain was applied to the TFT substrate. The alignment agent had a composition of N-methyl-2-pyrrolidone (NMP):butyl cellosolve (BC):solid content=66:30:4 (weight ratio). The same alignment agent was also applied to the CF substrate 40.

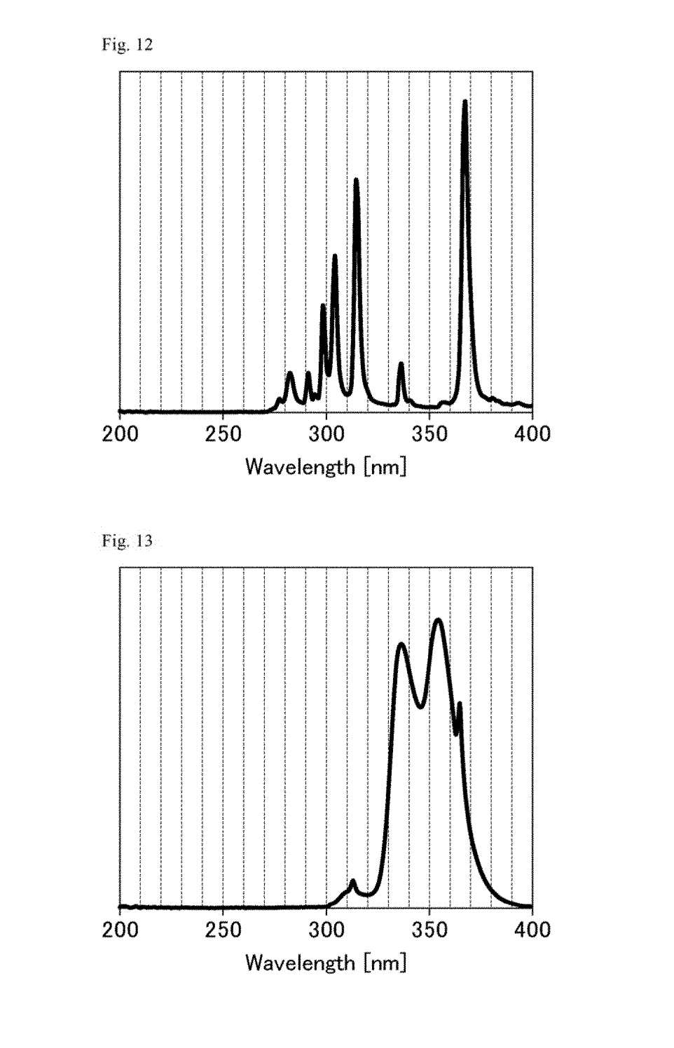

The TFT substrate 20 and the CF substrate 40 each with the alignment agent applied thereto were pre-baked at 70° C. for two minutes. The alignment films 50 formed by the pre-baking each had a thickness of 100 nm. After the pre-baking, the alignment films 50 were post-baked at 200° C. for 30 minutes. After the post-baking, irradiation with p-polarized ultraviolet rays in a direction inclined at 40° relative to the normal direction of the substrate was performed as exposure for alignment treatment. FIG. 12 is a view showing an irradiation spectrum of the alignment treatment in Example 4. The light source of the p-polarized ultraviolet rays used was a high-intensity point light source (produced by Ushio Inc., trade name: Deep UV lamp). Further, a shortcut filter that blocks light with a wavelength of 270 nm or shorter was used. The p-polarized ultraviolet rays with which the alignment films 50 were irradiated had an intensity measured with an accumulated UV meter (produced toy Ushio inc., trade name: UIT-250, photodetector type: UVD-S313) of 40 mJ/cm².

Next, a predetermined pattern was drawn with a sealing agent (produced by Kyoritsu Chemical & Co., Ltd., trade name: WORLD ROCK) on the CF substrate 40. Then, a liquid crystal was dropped to the TFT substrate 20 by one drop filling (ODF). The liquid crystal used was MLC6610 produced by Merck KGaA. The CF substrate 40 and the TFT substrate 20 were attached to each other in such a manner that the pretilt azimuths thereof were perpendicular to each other, and the liquid crystal was sealed in between the TFT substrate 20 and the CF substrate 40. This formed four domains different in the alignment direction of the liquid crystal molecules in each pixel. Arrows in FIG. 11 indicate the alignment directions of the liquid crystal molecules in the respective domains. The heat treatment was then carried out at 130° C. for 40 minutes. The formed liquid crystal layer 60 had a d·Δn (product of the thickness d and the refractive index anisotropy Δn) of 340 nm. A pair of polarizing plates was attached to the back side of the TFT substrate 20 and the viewing surface side of the CF substrate 40 in such a manner that the polarization axes were in a relation of crossed Nicols. Further, the backlight 10 equipped with an LED was mounted on the back side of the TFT substrate 20, thereby completing the VATN-mode liquid crystal display device of Example 4.

### <Characteristics Evaluation of Example 4>

### 1) Current-Voltage (I-V) Characteristics of TFT

The I-V characteristics of the TFT of Example 4 were analyzed before and after the exposure for alignment treatment in the same manner as in Example 1. As a result, the I-V characteristics were slightly changed before and after the exposure for alignment treatment. Specifically, the threshold voltage of the TFT was lowered by 0.14 V (ΔVth=−0.14 V) after the exposure.

### 2) Display Unevenness at a Gray Scale Value of 31

The screen lit at the gray scale value of 31 was visually observed to evaluate the display unevenness. As a result of the observation, the liquid crystal display device of Example 4 had favorable display quality without display unevenness (nonuniform DC charging due to TFT characteristics) through a neutral density filter (ND2 filter) that passes 50% of light.

As described above, the effects of the present invention were confirmed not only in the case where the alignment mode of the liquid crystal was the horizontal alignment mode (transverse electric field mode) as in Examples 1 and 2 but also in the case where the alignment mode was the VATN mode.

### EXAMPLE 5

Example 5 relates to a liquid crystal display device of the multi-domain vertical alignment (MVA) mode that is a vertical alignment mode characterized by polymer sustained alignment (PSA).

The TFT substrate of Example 5 had a CE structure shown in FIG. 10 and had the same cross-sectional structure as that of the TFT substrate of Example 4. The TFT substrate of Example 5, however, had a plan structure different from that of the TFT substrate of Example 4 in that an electrode slit was formed in the pixel electrode.

Also in Example 5, the alignment film was formed on the pixel electrode of the TFT substrate. The alignment film was also formed on the surface of the CF substrate on the side adjacent to the liquid crystal layer.

The alignment films were formed by the following procedure. First, an alignment agent containing, as a solid content, a polyimide polymer that included a cholestane structure and a cinnamate structure in the side chain was applied to the TFT substrate. The alignment agent had a composition of NMP:BC:solid content=66:30:4 (weight ratio). The same alignment agent was also applied to the CF substrate.

The TFT substrate and the CF substrate each with the alignment agent applied thereto were pre-baked at 70° C. for two minutes. The alignment films formed by the pre-baking each had a thickness of 100 nm. After the pre-baking, the alignment films were post-baked at 200° C. for 30 minutes.

Next, a predetermined pattern was drawn with a sealing agent (produced by Kyoritsu Chemical & Co., Ltd., trade name: WORLD ROCK) on the CF substrate. Then, a liquid crystal was dropped to the TFT substrate 20 by one drop filling (ODF). The liquid crystal used was MLC6610 (Merck KGaA) blended with, as a precursor of a methacrylate polymer layer, 0.3 wt % of biphenyl-4,4′-diyl bis(2-methylacrylate). The CF substrate and the TFT substrate were attached to each other, and the liquid crystal was sealed in between the substrates. The heat treatment was then carried out at 130° C. for 40 minutes. The formed liquid crystal layer had a d·Δn (product of the thickness d and the refractive index anisotropy Δn) of 340 nm.

Next, irradiation with non-polarized ultraviolet rays in the normal direction of the substrate was performed as the exposure for alignment treatment, while a direct current (DC) voltage of 20 V was applied between the pixel electrode provided in the TFT substrate and the common electrode provided in the CF substrate. FIG. 13 is a view showing an irradiation spectrum of the alignment treatment in Example 5. The light source of the non-polarized ultraviolet rays used was a black light fluorescent lamp (produced by Toshiba Corporation, trade name: FHF32BLB). No cut-off filter was used. The non-polarized ultraviolet rays had an intensity measured with an accumulated UV meter (produced by Ushio Inc., trade name: UIT-250, photodetector type: UVD-S365) of 5 J/cm². The irradiation with non-polarized ultraviolet rays photopolymerized biphenyl-4,4′-diyl bis(2-methylacrylate) in the liquid crystal, thereby forming a methacrylate polymer layer on the alignment films.

A pair of polarizing plates was attached to the back side of the TFT substrate and the viewing surface side of the CF substrate in such a manner that the polarization axes were in a relation of crossed Nicols. Further, an LED backlight was mounted on the back side of the TFT substrate, thereby completing the MVA-mode liquid crystal display device of Example 5 to which the PSA technique was applied.

### <Characteristics Evaluation of Example 5>

### 1) Current-Voltage (I-V) Characteristics of TFT

The I-V characteristics of the TFT of Example 5 were analyzed before and after the exposure for alignment treatment in the same manner as in Example 1. As a result, the I-V characteristics were slightly changed before and after the exposure for alignment treatment. Specifically, the threshold voltage of the TFT was lowered by 0.20 V (ΔVth=−0.20 V) after the exposure.

### 2) Display Unevenness at a Gray Scale Value of 31

The screen lit at the gray scale value of 31 was visually observed to evaluate the display unevenness. As a result of the observation, the liquid crystal display device of Example 4 had favorable display quality without display unevenness (nonuniform DC charging due to TFT characteristics) through a neutral density filter (ND2 filter) that passes 50% of light.

As described above, the effects of the present invention was confirmed also in the case where the PSA technique was used in combination.

Technical features mentioned in the examples of the present invention may be combined with each other to provide another embodiment of the present invention.

### [Additional Remarks]

An aspect of the present invention may be a liquid crystal display device including: a thin-film transistor substrate; and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the oxide semiconductor containing indium, tin, zinc, and oxygen, the alignment film having a photofunctional group. Since the liquid crystal display device according to the aspect includes a channel layer including an oxide semiconductor (In—Sn—Zn—O oxide semiconductor) that contains indium, tin, zinc, and oxygen, damage of the channel layer during channel etching can be prevented. Degradation of the current-voltage (I-V) characteristics of the TFT due to the photo-alignment treatment can be thus prevented. This can prevent nonuniform DC charging due to TFT characteristics, leading to a liquid crystal display device excellent in display quality.

The photofunctional group may include at least one selected from the group consisting of a cinnamate structure, a chalcone structure, a cyclobutane structure, an azobenzene structure, a stilbene structure, a coumarin structure, and a phenyl ester structure. These structures enable alignment treatment with light.

A polymer layer including at least one of the acrylate structure and the methacrylate structure may be provided between the alignment film and the liquid crystal layer. Such a polymer layer can be produced by PSA. The polymer layer is preferred as it can be formed by efficiently radically polymerizing a precursor (e.g., monomer) contained in the liquid crystal with light

The technical features of the present invention described above may be appropriately combined within the spirit of the present invention.

### REFERENCE SIGNS LIST

10: Backlight

20: Thin film transistor (TFT) substrate

21: Substrate

22: Gate line

22g: Gate electrode

23: Gate insulating film

24: Channel layer

25: Source line

25d: Drain electrode

25s: Source electrode

26: Inorganic insulating film

27: Acrylic resin film

28: Auxiliary capacitance electrode

29: Auxiliary capacitance insulating film

30: Pixel electrode

40: Color filter (CF) substrate

50: Alignment film

60: Liquid crystal layer

1. A liquid crystal display device comprising:
a thin-film transistor substrate; and
a liquid crystal layer,
the thin-film transistor substrate comprising a thin-film transistor having a channel etch structure and an alignment film,
the thin-film transistor comprising a gate electrode, a gate insulating film, a channel layer containing an oxide semiconductor, and a pair of a source electrode and a drain electrode in the stated order,
the oxide semiconductor containing indium, tin, zinc, and oxygen,
the alignment film having a photofunctional group.

2. The liquid crystal display device according to claim 1,
wherein the photofunctional group includes at least one selected from the group consisting of a cinnamate structure, a chalcone structure, a cyclobutane structure, an azobenzene structure, a stilbene structure, a coumarin structure, and a phenyl ester structure.

3. The liquid crystal display device according to claim 1, further comprising
a polymer layer including at least one of an acrylate structure and a methacrylate structure between the alignment film and the liquid crystal layer.
